(19) United States
(12) Patent Application Publication
(10) Pub. No.: US 2015/0235693 A1
(43) Pub. Date: Aug. 20, 2015

(54) MEMORY SYSTEM INCLUDING SEMICONDUCTOR MEMORY DEVICE AND REFRESH OPERATION METHOD THEREOF

(71) Applicant: SK hynix Inc., Gyeonggi-do (KR)

(72) Inventor: Choung-Ki SONG, Gyeonggi-do (KR)

(21) Appl. No.: 14/319,896

(22) Filed: Jun. 30, 2014

(30) Foreign Application Priority Data
Feb. 20, 2014 (KR) 10-2014-0019556

(51) Int. Cl. G11C 11/406

(52) U.S. Cl. CPC G11C 11/40603; G11C 11/40618

(57) ABSTRACT

A memory system includes a memory module including a plurality of memories and a memory controller suitable for controlling an operation timing of each of the memories, wherein the memories enter a refresh operation mode simultaneously in response to a refresh operation command of the memory controller and individually perform a refresh operation according to the operation timing.

### CROSS-REFERENCE TO RELATED APPLICATIONS

The present application claims priority of Korean Patent Application No. 10-2014-0019556, filed on Feb. 20, 2014, which is incorporated herein by reference in its entirety.

### BACKGROUND

1. Field

Exemplary embodiments of the present invention relate to a semiconductor memory device, and more particularly, to a memory system including a semiconductor memory device and a refresh operation method thereof.

2. Description of the Related Art

A semiconductor device including a semiconductor memory device such as a Dynamic Random Access Memory (DRAM), is widely used in diverse electronic systems. Especially the semiconductor memory device is for storing data used in the electronic systems. Taking DRAM as an example, each unit cell of a semiconductor memory device is formed of one transistor and one capacitor, and data is stored by way of a charge accumulated in the capacitor. However, a problem arises as the charge leaks over time because it is difficult to cut off the capacitor from the peripheral region over the semiconductor substrate. As a result, the data stored in the unit cell may be damaged or lost. To sustain the charge stored in the capacitor, the semiconductor memory device performs what is known as a refresh operation.

A semiconductor memory device performs a refresh operation by sequentially varying its internal address based on an external command. When a refresh operation mode begins based on an external command, word lines of a memory cell are sequentially selected as a row address is sequentially increased at a predetermined cycle. The charges stored in a capacitor corresponding to the selected word line are amplified by a sense amplifier and then stored back into the capacitor. Through a series of refresh operations, the stored data is retained without being damaged. While in refresh operation mode, more word lines are simultaneously enabled, and more charges stored in the corresponding capacitors are sense-amplified compared to a general operation mode. This means that peak current is raised while in refresh operation mode resulting in power noise.

A semiconductor memory device is packaged in conformity to the system where the semiconductor memory device is mounted in an environment where the capacity and operation rates required by systems are always increasing. For example, several semiconductor memory devices mounted on a personal computer (PC) are packaged in the form of a module that is integrated on a Printed Circuit Board (PCB), and the module is inserted into a slot of the PC. A typical form of module among the modules packaged in conformity to a system is a Dual In-line Memory Module (DIMM). A plurality of memory devices mounted on the DIMM may be grouped and operated on the basis of rank.

FIG. 1 is a timing diagram describing a refresh operation of a typical DIMM.

Referring to FIG. 1, the typical DIMM includes eight memory devices DRAM0 to DRAM7 in one rank RANK0, and the timing diagrams of the refresh operations of the memory devices DRAM0 to DRAM7 are shown in the drawing.

As described above, since the memory devices mounted on the memory module are grouped and operated together, the refresh operations are performed simultaneously as shown in FIG. 1. As the simultaneous refresh operations raise the peak current, noise may be produced in the power source voltage VDD or the ground voltage VSS (see FIG. 1).

### SUMMARY

The present invention is directed at a refresh operation method of a memory module, which can be represented in multiple embodiments in various semiconductor memory devices and memory systems.

In accordance with an embodiment of the present invention, a memory system includes a memory module including a plurality of memories, and a memory controller suitable for controlling an operation timing of each of the memories, wherein the memories enter a refresh operation mode simultaneously in response to a refresh operation command of the memory controller and individually perform a refresh operation according to the operation timing.

In accordance with another embodiment of the present invention, a method for performing a refresh operation in a memory system including a plurality of memories includes setting an operation timing of each of the memories, inputting a refresh operation command to the memories to enter a refresh operation mode simultaneously, and individually performing the refresh operation in each of the memories at a set operation timing in the refresh operation mode.

In accordance with yet another embodiment of the present invention, a semiconductor memory device includes a Mode Register Set (MRS) unit suitable for outputting a delay control signal corresponding to an input data in response to a mode register set control signal, and a delay control unit suitable for controlling a delay amount of an input path of a refresh operation control signal in response to the delay control signal.

### BRIEF DESCRIPTION OF THE DRAWINGS

FIG. 1 is a timing diagram illustrating a refresh operation of a typical Dual In-line Memory Module (DIMM).

FIG. 2 is a block view illustrating a memory system in accordance with an embodiment of the present invention.

FIG. 3 is a block view illustrating a semiconductor memory device in accordance with an embodiment of the present invention.

FIG. 4 is a flowchart describing an operation of the memory system shown in FIG. 2.

FIG. 5 is a timing diagram illustrating the timings of the refresh operations of memories shown in FIG. 2.

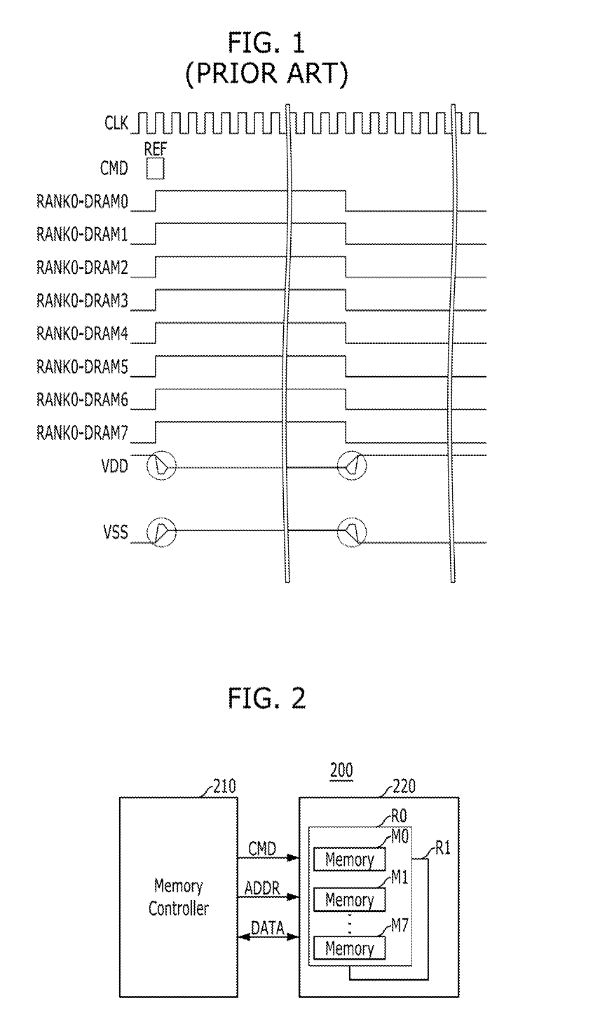

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts in the various figures and embodiments of the present invention.

FIG. 2 is a block view illustrating a memory system in accordance with an embodiment of the present invention.

Referring to FIG. 2, the memory system 200, in accordance with an embodiment of the present invention, may include a memory controller 210 and a memory module 220. The memory module 220 may include a plurality of memories M.

The memories M are divided into a plurality of groups R and operate on the basis of a group R in response to a command CMD and an address ADDR that are transmitted from the memory controller 210. The memories M of a group perform a corresponding operation at predetermined timings respectively. The timings may be set differently under the control of the memory controller 210. A method for setting an operation timing of each memory will be described in detail below.

Taking a brief look at the method, memories M0 to M7 of a first group R0 enter a refresh operation mode together. The memories M0 to M7 perform a refresh operation according to a timing that is pre-set internally. The memory controller 210 may set the operation timing of each of the memories M0 to M7 differently.

The process of setting the operation timing and performing the refresh operation in each memory will be described in detail.

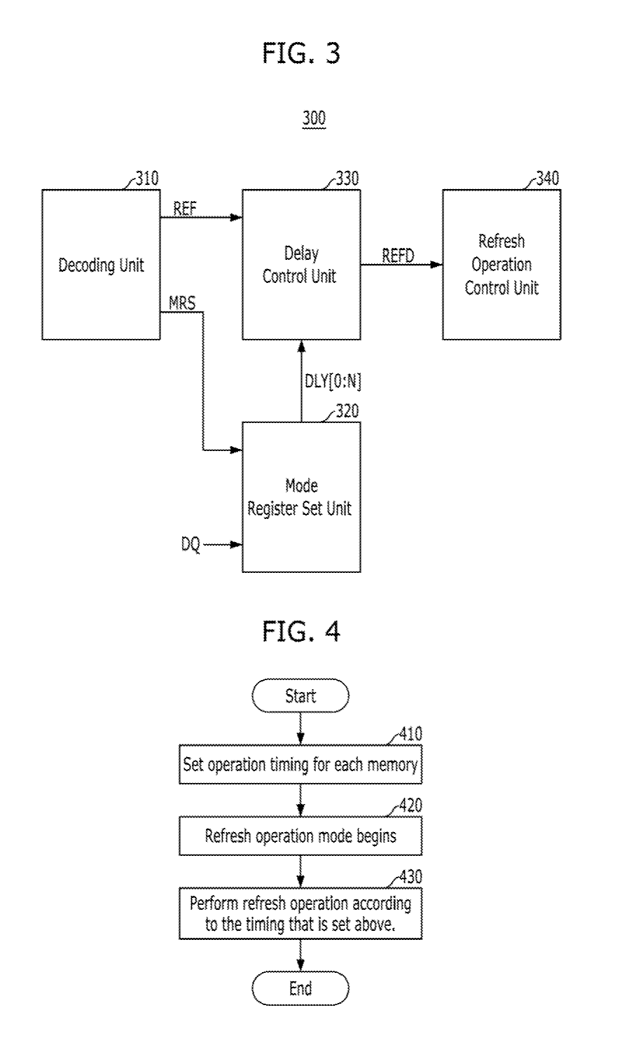

FIG. 3 is a block view illustrating a semiconductor memory device in accordance with an embodiment of the present invention.

The semiconductor memory device 300, in accordance with an embodiment of the present invention, may form the memory M of FIG. 2. Referring to FIG. 3, the semiconductor memory device 300 may include a decoding unit 310, a Mode Register Set (MRS) unit 320, and a delay control unit 330.

The decoding unit 310 decodes a command inputted from an external device, e.g., the memory controller 210 of FIG. 2, and generates a corresponding control signal. When the logic level combination of an external command corresponds to a mode register set operation, the decoding unit 310 generates a mode register set control signal MRS. When the combination of an external command corresponds to a refresh operation, the decoding unit 310 generates a refresh operation control signal REF.

The mode register set unit 320 outputs a delay control signal DLY[0:N] of bits corresponding to an input data DQ in response to the mode register set control signal MRS that is outputted from the decoding unit 310. For example, the data DQ may include an address ADDR or a data DATA inputted from the memory controller 210, which is shown in FIG. 2. In short, the bit value of the delay control signal DLY[0:N] outputted from the mode register set unit 320 may be set by the memory controller 210.

The delay control unit 330 may decide an internal delay amount in response to the delay control signal DLY[0:N], delay the refresh operation control signal REF generated in the decoding unit 310 by the decided delay amount, and output a delayed refresh operation control signal REFD. The internal delay amount of the delay control′ unit 330 may be decided based on the bit value of the delay control signal DLY[0:N]. The delay control unit 330 may include a synchronous or asynchronous delay circuit. Since a delay circuit that delays a signal by a delay amount decided in response to a bit signal is a known technology, a detailed description on the delay circuit is not provided.

In short, the semiconductor memory device, in accordance with an embodiment of the present invention, may set the delay of a refresh operation command input path by using the control signals during a mode register set operation. In this way, the timing for a refresh operation of the semiconductor memory device may be decided.

The semiconductor memory device 300, in accordance with an embodiment of the present invention, may further include a refresh operation control unit 340. The refresh operation control unit 340 may control the refresh operation of the semiconductor memory device 300 in response to the delayed refresh operation control signal REFD, which is outputted from the delay control unit 330.

The operations of the memory system 200 and the semiconductor memory device 300 having the above-described structures are described with reference to FIG. 4.

FIG. 4 is a flowchart describing an operation of the memory system 200.

First, in step S410, operation timing for each of the memories M0 to M7 is set based on a control signal inputted from the memory controller 210. This may be performed through a mode register set operation. The memory controller 210 may generate control signals for a mode register set operation, input the generated control signals into the memories M0 to M7, and set the operation timing for each of the memories M0 to M7 differently.

Subsequently, in step S420, all the memories M0 to M7 enter a refresh operation mode in response to a refresh operation command of the memory controller 210.

After entering the refresh operation mode, in step S430, each of the memories M0 to M7 performs a refresh operation according to the timing that is set in the step S410.

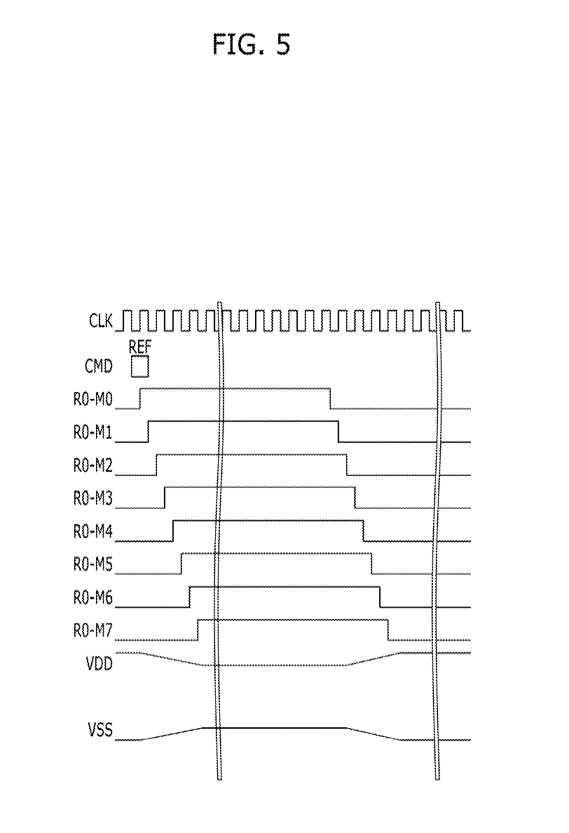

FIG. 5 is a timing diagram illustrating the timing of the refresh operations of the memories M0 to M7 that operate as described above.

Referring to FIG. 5, the memories M0 to M7 enter the refresh operation mode in response to the refresh operation command generated in the memory controller 210. To be more accurate, the memories M0 to M7 perform the refresh operations, respectively, in synchronization with the delayed refresh operation control signals REFD (see FIG. 3) that are obtained internally. The delay amount, which is the timing for the refresh operation, may be set differently by the memory controller 210. As shown in FIG. 5, the delay amount may be set in such a manner that the refresh operations of the memories M0 to M7 may be performed sequentially, and this may prevent noise from occurring in the power source voltage.

In the memory system, in accordance with embodiments of the present invention described above, it is possible to prevent a peak in current by staggering the operation timing of each memory, although the memories perform their refresh operation synchronously.

According to an embodiment of the present invention, power noise may be prevented in a memory module including a plurality of memory devices by controlling the timings for the refresh operations of the semiconductor memory devices.

While the present invention has been described with respect to the specific embodiments, it will be apparent to those skilled in the art that various changes and modifications may be made without departing from the spirit and scope of the invention as defined in the following claims.

What is claimed is:

1. A memory system, comprising:
a memory module including a plurality of memories; and
a memory controller suitable for controlling an operation timing of each of the memories,
wherein the memories enter a refresh operation mode simultaneously in response to a refresh operation command of the memory controller and individually perform a refresh operation according to the operation timing.

2. The memory system of claim 1, wherein the memories are divided into multiple groups, and memories of each group enter the refresh operation mode simultaneously and individually perform the refresh operation according to the operation timing that is set differently for each memory.

3. The memory system of claim 1, wherein the memories adjust a delay amount of an input path of the refresh operation command in response to a Mode Register Set (MRS) command of the memory controller.

4. The memory system of claim 3, wherein each of the memories includes:
a decoding unit suitable for decoding the refresh operation command and the mode register set command and generating a refresh operation control signal and a mode register set control signal;
a mode register set unit suitable for outputting a delay control signal of a bit corresponding to an input data in response to the mode register set control signal;
a delay control unit suitable for deciding an internal delay amount in response to the delay control signal, delaying the refresh operation control signal by a decided internal delay amount, and generating a delayed refresh operation control signal; and
a refresh operation control unit suitable for performing the refresh operation in response to the delayed refresh operation control signal.

5. The memory system of claim 1, wherein the memory module is a Dual In-line Memory Module (DIMM).

6. The memory system of claim 5, wherein the memories are semiconductor memory devices mounted on the DIMM.

7. A method for performing a refresh operation in a memory system including a plurality of memories, comprising:
setting an operation timing of each of the memories;
inputting a refresh operation command to the memories to enter a refresh operation mode simultaneously; and
individually performing the refresh operation in each of the memories at a set operation timing in the refresh operation mode.

8. The method of claim 7, wherein the setting of the operation timing of each of the memories includes:
inputting a mode register set control signal to each of the memories; and
controlling a delay amount of an input path of the refresh operation command based on the mode register set control signal.

9. The method of claim 8, wherein in the controlling of the delay amount of the input path of the refresh operation command based on the mode register set control signal,
delay amounts of the memories are adjusted to be different from each other.

10. A semiconductor memory device, comprising:
a Mode Register Set (MRS) unit suitable for outputting a delay control signal corresponding to an input data in response to a mode register set control signal; and
a delay control unit suitable for controlling a delay amount of an input path of a refresh operation control signal in response to the delay control signal.

11. The semiconductor memory device of claim 10, further comprising:
a decoding unit suitable for decoding a refresh operation command and a mode register set command and generating the refresh operation control signal and the mode register set control signal; and
a refresh operation control unit suitable for performing a refresh operation in response to the refresh operation control signal that is transmitted through the input path.
